(19) United States
(12) Patent Application Publication
(10) Pub. No.: US 2026/0293554 A1
(43) Pub. Date: Sep. 24, 2026

(54) ANISOTROPIC THERMAL ETCHING OF SiO2

(71) Applicant: Lam Research Corporation, Fremont, CA (US)

(72) Inventors: Eric A. HUDSON, Berkeley, CA (US); Prabhat KUMAR, Fremont, CA (US)

(21) Appl. No.: 19/474,131

(22) PCT Filed: May 3, 2024
(86) PCT No.: PCT/US2024/027794

§ 371 Date: Oct. 9, 2025

Related U.S. Application Data
(60) Provisional application No. 63/500,826, filed on May 8, 2023.

(51) Int. Cl. H10P 50/28; H01J 37/32; H10P 14/60; H10P 14/69; H10P 72/00

(52) U.S. Cl. CPC H10P 50/283; H01J 37/3244; H10P 14/6339; H10P 14/6902; H10P 72/0421; H01J 2237/3341

(57) ABSTRACT

A method for etching features in a stack is provided. A plurality of cycles is provided. A thermal etch step for etching the features in the stack is provided in the cycle, where the stack comprises at least one silicon oxide layer, and the thermal etch step, comprises providing a thermal etch gas in vapor phase comprising a halogen containing vapor or gas and a vapor catalyst and providing thermal energy to drive a reaction that etches the features in the stack. A passivation step for depositing a passivation layer on sidewalls of the features is provided in the cycle.

### CROSS-REFERENCE TO RELATED APPLICATION

This application claims the benefit of priority of U.S. Application No. 63/500,826, filed May 8, 2023, which is incorporated herein by reference for all purposes.

### BACKGROUND

In forming semiconductor devices, etch layers may be etched to form memory holes or lines or other semiconductor features. Some semiconductor devices may be formed by etching a single layer of silicon dioxide (SiO2), for example, to form a capacitor in dynamic access random memory (DRAM). Other semiconductor devices may be formed by etching a stack of bilayers of alternating silicon dioxide (oxide) and silicon nitride (nitride) (ONON), or alternating silicon dioxide and polysilicon (OPOP). Such stacks may be used in memory applications and three dimensional “not and” gates (3D NAND). These stacks tend to require relatively high aspect ratio (HAR) etching of the dielectrics. For high aspect ratio etches, examples of desired etch characteristics are high etch selectivity to the mask (such as an amorphous carbon mask), low sidewall etching with straight profiles, and high etch rate at the etch front. Some high aspect ratio etches result in tapered features that are much wider at the top than the bottom. Such features may increase device failure or limit device density, device performance, and device depth. Etching may also be used for punch processes, shallow trench isolation, and carbon mask opening.

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method for etching features in a stack is provided. A plurality of cycles is provided. A thermal etch step for etching the features in the stack is provided in the cycle, where the stack comprises at least one silicon oxide layer, and the thermal etch step, comprises providing a thermal etch gas in vapor phase comprising a halogen containing vapor or gas and a vapor catalyst and providing thermal energy to drive a reaction that etches the features in the stack. A passivation step for depositing a passivation layer on sidewalls of the features is provided in the cycle.

In another manifestation, a method for etching features in a stack comprising a plurality of cycles is provided. Each cycle comprises providing a plasma etch and providing a thermal etch for etching features in the stack, wherein the stack comprises at least bilayers, wherein at least one layer of the at least bilayers is a silicon oxide layer. The thermal etch comprises providing a thermal etch gas in vapor phase comprising a halogen containing vapor or gas and a vapor catalyst. Thermal energy is provided to drive a reaction that etches features in the stack.

In another manifestation, an apparatus for etching a substrate is provided. A reaction chamber is configured to provide a pressure between about 0.2-10 Torr in the reaction chamber. A substrate support is configured to support the substrate in the reaction chamber. At least one inlet introduces a gas mixture to the reaction chamber. A halogen vapor or gas source provides a halogen vapor or gas to the at least one inlet. A vapor catalyst source provides a vapor catalyst to the at least one inlet. At least one of a passivation gas source and an etch plasma gas source are connected to the at least one inlet. A heater provides thermal energy to the substrate. An outlet removes vapor from the reaction chamber. A controller is configured to provide a cyclical process. Each cycle comprises a thermal etch step, at least one of a passivation step, and a plasma etch.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of some embodiments.

FIGS. 2A-E are schematic cross-sectional views of a stack processed according to some embodiments.

FIG. 3 is a high level flow chart of some embodiments.

FIGS. 4A-F are schematic cross-sectional views of a stack processed according to some embodiments.

FIG. 5 is a schematic view of an etch chamber that may be used in some embodiments.

FIG. 6 is a schematic view of a computer system that may be used in practicing some embodiments.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Dry development of high aspect ratio contacts requires strict control of the tapering angle of the sidewall. Various methods try to limit lateral critical dimension (CD) differences between top and bottom parts of the etched structures. With the recent development of 3D NAND memory having thicker structures with an increased number of ONON or OPOP bilayers, the demand for tight control of top and bottom geometries is especially significant. In case the taper (difference between the top and bottom CDs) increases, subsequent steps of device manufacturing will be at risk that will impact device performance. In the current technology, reactive ion etching of high aspect ratio structures relies on sidewall deposition to protect CD lateral erosion. A delicate balance between etching and sidewall deposition is especially difficult to maintain for high aspect ratio features. As a result, high aspect ratio dry development is limited to thinner structures and requires significant complex development to enable a thick stack to be etched.

### CYCLE OF THERMAL ETCHING WITH PASSIVATION

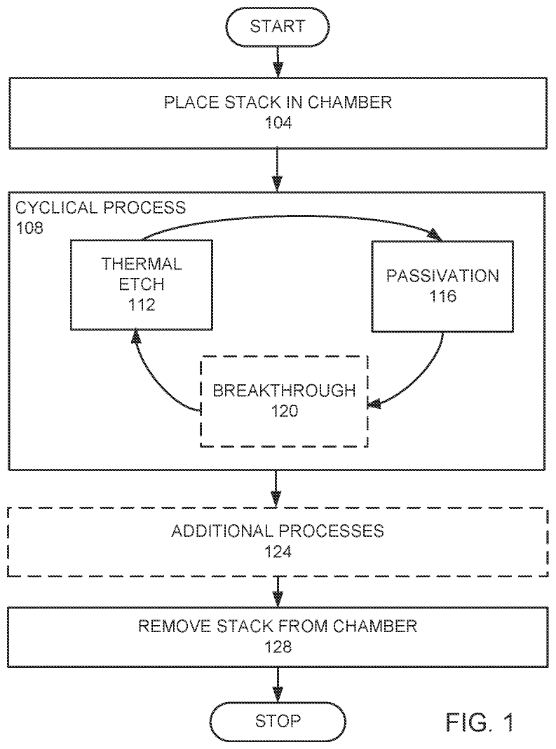

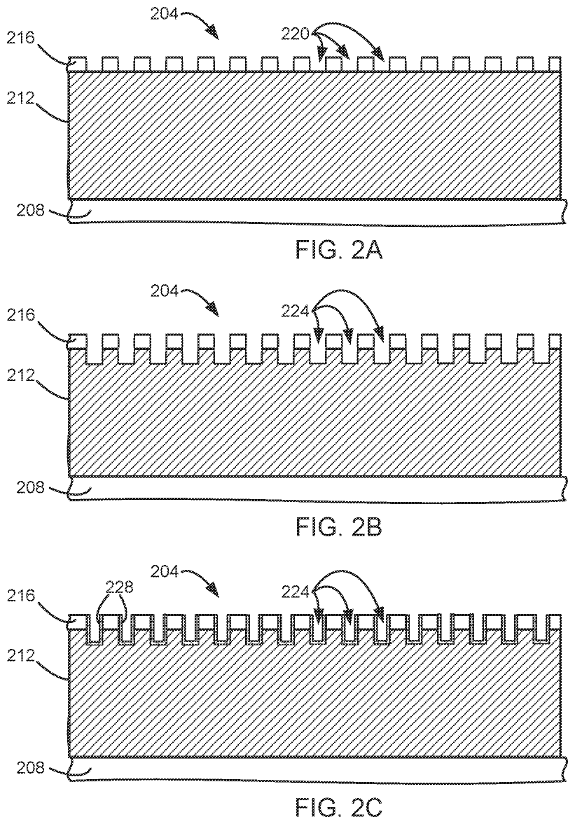

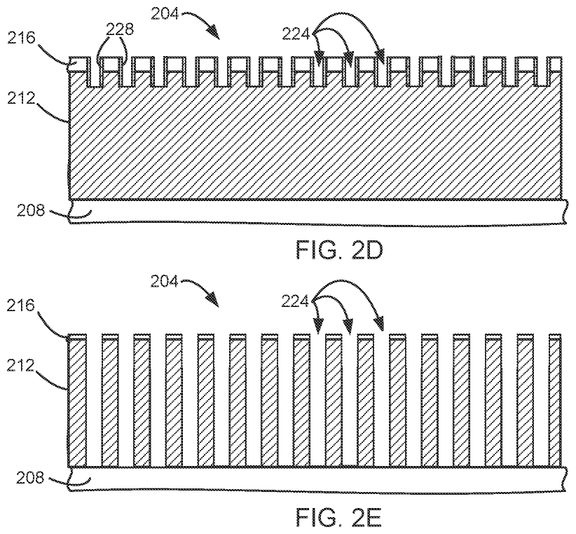

Some embodiments described herein provide deeper high aspect ratio features etched in a stack with reduced tapering and reduced bowing so that widths of the features near the top of the features are about equal to widths of the features near the bottoms of the features. To facilitate understanding, FIG. 1 is a high level flow chart that may be used in some embodiments. In some embodiments, a stack is placed in an etch chamber (step 104). FIG. 2A is a schematic cross-sectional view of a stack 204 that may be processed according to some embodiments. The stack 204 may be formed over a substrate 208. Stack 204 is a layer of silicon oxide (SiO2) 212 under a silicon nitride (SiN) mask 216 with mask features 220. In some embodiments, one or more layers may be between the layer of silicon oxide 212 and the substrate 208. In some embodiments, one or more layers may be between the layer of silicon oxide 212 and the SiN mask 216. In some embodiments, the mask features 220 have a CD of less than 20 nanometers (nm). A silicon oxide layer includes silicon oxide based layers. Silicon oxide based layers are silicon oxide layers that may also include one or more dopants. Similarly, a polysilicon layer also includes a polysilicon layer with at least one dopant resulting in a polysilicon based layer. A silicon nitride layer includes a silicon nitride layer with at least one dopant forming a silicon nitride based layer.

A cyclical process (step 108) is provided to etch the stack. In some embodiments, the cyclical process (step 108) comprises one or more cycles of a thermal etch step (step 112), a passivation step (step 116), and a breakthrough step (step 120). In some embodiments, the cycles do not have a breakthrough step (step 120). In some embodiments, two or more of the processes are performed in-situ in the same processing chamber.

### Thermal Etch

In some embodiments, the thermal etch step (step 112) comprises providing a thermal etch gas and providing thermal energy to drive a reaction that causes the thermal etch gas to etch the stack 204. In some embodiments, the thermal etch gas modifies part of the stack. In some embodiments, the thermal etch step is a plasma free process. In some embodiments, the thermal etch gas comprises a halogen containing vapor and a vapor catalyst, where the vapor catalyst comprises an organic solvent and/or water, an additive, and a carrier gas. In some embodiments, the thermal etch gas is provided cyclically by providing a step of providing the halogen containing gas and a step of providing a vapor and vapor catalyst sequentially. In some embodiments, during the thermal etch step the halogen containing gas and the vapor with catalyst are provided simultaneously. In some embodiments, the halogen containing gas is a hydrogen fluoride (HF) gas. The terms “vapor phase” and “gas phase” are used interchangeably in this disclosure. The halogen containing vapor and the vapor catalyst form a gas mixture. The additive may have particular properties or a particular composition, as described further below. The substrate may be etched at low pressure using thermal energy, for example in a vacuum reaction chamber. In such cases, the substrate is not exposed to plasma during the etching reaction. The substrate may be etched in a selective manner, such that one or more materials are targeted for removal while other materials are etched to a lesser degree. In some embodiments, silicon oxide is the material that is targeted to be selectively removed. In some embodiments, the thermal energy is used to drive an endothermic reaction causing the thermal etch gas to selectively etch a first material of the stack with respect to a second material of the stack. One advantage of the disclosed techniques is that they achieve a high degree of selectivity during etching. Another advantage of the disclosed techniques is that they provide extremely precise control of the etching rate and etch removal amount, especially compared to other thermally-driven etch processes. The thermal etch step is described in WO 2021/202411A1, published on Oct. 7, 2021, entitled “Selective precision etching of semiconductor materials,” which is incorporated by reference for all purposes.

In some embodiments, examples of organic solvents, carrier gases, and additives are as follows:

### Organic Solvent

### Alcohols

In certain implementations, the organic solvent may be an alcohol. The alcohol can be an alcohol having a formula of X—C(R)ₙ(OH)—Y, where:
n is 1;
each X and Y can be independently selected from hydrogen, —[C(R¹)₂]ₘ—C(R²)₃, or OH, wherein each R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10; and each R independently is selected from hydrogen, hydroxyl, aliphatic, haloaliphatic, haloheteroaliphatic, heteroaliphatic, aromatic, aliphatic-aromatic, heteroaliphatic-aromatic, or any combinations thereof.

In some embodiments, each R, R¹, and R² independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the alcohol may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In other embodiments, when at least one of X or Y═—[C(R¹)₂]ₘ—C(R²)₃¬ or R is hydrogen and m is 1, the alcohol can be a C₃ alcohol. For instance, if at least one R¹ and one R² are absent, then the C₃ alcohol can be a C₃ alkenol (e.g., allyl alcohol). In another instance, R and one R² together can form a ring(such as cycloaliphatic), then the C₃ alcohol can be a cyclopropanol or 2-cyclopropenol.

In yet other embodiments, when at least one of X or Y═—[C(R¹)₂]ₘ—C(R²)₃¬ or R is hydrogen and m is 2, the alcohol can be a C₄ alcohol. For instance, if at least one R¹ and one R² are absent, then the C₄ alcohol can be a C₄ alkenol (e.g., 2-buten-1-ol or 3-buten-1-ol). In another instance, R and one R² together can form a ring (such as cycloaliphatic), then the C₄ alcohol can be a C4-cyclic alcohol (e.g., cyclobutanol or cyclopropylmethanol). In yet another instance, if both X and Y are not OH, then the C4 alcohol can be a C4-branched alcohol (e.g., 2-butanol, isobutanol, or tert-butanol).

In some instances, when X═OH and Y═—[C(R¹)₂]ₘ—C(R²)₃¬, the alcohol can be a diol. In other instances, when at least one X or Y═—[C(R¹)₂]ₘ—C(R²)₃¬¬ and at least one R¹═OH or one R²═OH, or when R═OH, the alcohol can be a diol. Example diols include, but are not limited to, 1,4-butane diol, propylene-1,3-diol, and the like.

In other instances, when X═Y═OH, the alcohol can be a triol. In yet other instances, when X═R═OH, the alcohol can be a triol. In some instances, when at least one of X or Y is —[C(R¹)₂]ₘ—C(R²)₃ and one R¹ and at least one R² is OH, the alcohol can be triol. In other instances, when R═OH and X═—[C(R¹)₂]ₘ—C(R²)₃ and one R¹ and at least one R² is OH, the alcohol can be triol. Example triols include, but are not limited to, glycerol or glycerine derivatives thereof.

In particular embodiments, when R═cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol (e.g., an optionally substituted heterocyclyl substituted with or more hydroxyls, such as furfuryl alcohol). In other embodiments, when at least one of X or Y is [C(R¹)₂]ₘ—C(R²)₃ and one R¹ and at least one R² is cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol.

In various embodiments, the alcohol may have between 1-10 carbon atoms. The alcohol may be a primary alcohol, a secondary alcohol, or a tertiary alcohol. In some cases, the alcohol may be selected from the group consisting of methanol, ethanol, 1-propanol, 2-propanol, 1-butanol, 2-butanol, t-butanol, 1-pentanol, 1-hexanol, 1-heptanol, 1-octanol, 1-nonanol, 1-decanol, and combinations thereof.

### Laboratory Solvents

In these or other cases, the organic solvent may include a laboratory-type solvent such as acetonitrile, dichloromethane, carbon tetrachloride, or a combination thereof.

### Ketones

In some embodiments, the organic solvent may be a ketone.

The organic solvent can also be a ketone having a formula of X—[C(O)]ₙ—Y, where:
n is an integer from 1 to 2;
each X and Y can be independently selected from —C(R¹)₃, —R², or [C(R3)₂]ₘ—C(O)—R⁴, wherein each R¹, R², R³, and R⁴ can be independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
in which R³ and R⁴, taken together with the atom to which each is attached, can optionally form a cycloaliphatic or cycloheteroaliphatic, and in which X and Y, taken together with the atom to which each is attached, can optionally form a cycloaliphatic or cycloheteroaliphatic; and
m is an integer from 0 to 10.

In some embodiments, each R¹, R², R³, and R⁴, independently, are alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the organic solvent may further be substituted with one or more substituents, such as aldehyde (—C(O)H), oxo (═O), alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof. One example ketone is acetone.

In some embodiments, when X and Y, taken together with the atom to which each is attached, form a cycloaliphatic or cycloheteroaliphatic, the organic solvent can be a cyclic ketone. Example cyclic ketones include cyclohexanone, cyclopentanone, and the like.

In other embodiments, when at least one of X or Y═[C(R³)₂]ₘ—C(O)—R⁴, the organic solvent can be a diketone. Example diketones include diacetyl, 2,3-pentanedione, 2,3-hexanedione, 3,4-hexanedione, acetylacetone, acetonylacetone, and the like, as well as halogenated forms thereof, such as hexafluoroacetylacetone.

In further embodiments, when at least one of X or Y═[C(R³)₂]ₘ—C(O)—R⁴ and X and Y, taken together with the atom to which each is attached, forms a cycloaliphatic or cycloheteroaliphatic, the organic solvent can be a cyclic diketone. Example cyclic diketones include dimedone, 1,3-cyclohexanedione, and the like.

In some instances, when X═—CH3, the organic solvent can have Y═—C(R¹)₃, in which at least one R¹ is C₂₋₁₀ hydroxyl, aliphatic, haloaliphatic, haloheteroaliphatic, heteroaliphatic, aromatic, aliphatic-aromatic, heteroaliphatic-aromatic, or any combinations thereof. Example materials can include methyl propyl ketone, methyl butyl ketone, hydroxyacetone, and the like.

In other instances, when X═—CH₃, the organic solvent can have Y═—R², in which at least one R² is C₂ alkenyl, C₃₋₁₀ aliphatic, haloaliphatic, haloheteroaliphatic, heteroaliphatic, aromatic, aliphatic-aromatic, heteroaliphatic-aromatic, or any combinations thereof. Example materials can include methyl vinyl ketone, methyl propyl ketone, methyl butyl ketone, and the like.

In yet other instances, when at least one of X or Y=aromatic, aliphatic-aromatic, or heteroaliphatic-aromatic, the organic solvent can be an aromatic ketone. Example materials include acetophenone, benzophenone, benzylacetone, 1,3-diphenylacetone, cyclopentyl phenyl ketone, and the like.

In certain embodiments where the organic solvent includes a ketone, the ketone may be selected from acetone and acetophenone. One or more additional ketones and/or other organic solvents described herein may be provided, as well.

### Alkanes

In some embodiments, the organic solvent may be an alkane. In certain embodiments, the alkane may be an acyclic branched or unbranched hydrocarbon having the general formula CₙH₂ₙ₊₂. Example acyclic alkanes include, but are not limited to, pentane, hexane, octane, and combinations thereof. In certain other embodiments, the alkane may be a cyclic hydrocarbon. Example cyclic hydrocarbons include, but are not limited to, cyclopentane, cyclohexane, and combinations thereof.

### Aromatic Solvents

In some embodiments, the organic solvent may be an aromatic solvent. As used herein, “aromatic” means a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Hückel rule (4n+2). The point of attachment to the parent structure typically is through an aromatic portion of the condensed ring system. In some cases, an aromatic solvent may be selected from toluene and benzene.

### Ethers

In some embodiments, the organic solvent may be an ether having a formula of X—O—Y or X—O—[C(R)₂]ₙ—O—Y, where:
n is an integer from 1 to 4;
each X and Y can be independently selected from —[C(R¹)₂]ₘ—C(R²)₃ or —R³ or —[C(R⁴)₂]ₚ—O—┌C(R⁵)₂┐ₘ—C(R⁶)₃, wherein each of R¹, R², R³, R⁴, R⁵, R⁶, and R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10 and p is an integer from 1 to 10;
in which X and Y, taken together with the atom to which each is attached, can optionally form a cycloheteroaliphatic group.

In some embodiments, each R, R¹, R², R³, R⁴, R⁵, and R⁶ independently are selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the ether may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X and Y are taken together with the atom to which each is attached in order to form a cycloheteroaliphatic group, the organic solvent is a cyclic ether, such as acetal, dioxane, dioxolane, etc. In some embodiments, when n=1 and each R=H, X, and Y taken together form a six, seven, eight, nine, or ten-membered ring. Example ethers include, but are not limited to, 1,3-dioxolane, or derivatives thereof. In other embodiments, when n=2 and R=H, X, and Y form a seven, eight, nine, or ten-membered ring. Example ethers include, but are not limited to, 1,4-dioxane, or derivatives thereof. In yet other embodiments, when n=1 or n=2, then R is aliphatic, haloaliphatic, haloheteroaliphatic, heteroaliphatic, aromatic, aliphatic-aromatic, heteroaliphatic-aromatic, or any combinations thereof. Example cyclic ethers include tetrahydrofuran, 2-methyltetrahydrofuran, 2-methyl-1,3-dioxolane, and the like.

In other embodiments, when at least one of X or Y=aromatic, the organic solvent can be an aromatic ether. Example aromatic ethers include anisole, diphenyl ether, and the like.

In some embodiments, when at least one of X or Y=cycloaliphatic, the organic solvent can be a cycloalkyl ether. Example cycloalkyl ethers include cyclopentyl methyl ether, cyclohexyl methyl ether, and the like.

In other embodiments, when at least one of X or Y═—[C(R⁴)₂—O]ₚ—C(R⁶)₃, the organic solvent can be a glycol based ether. Example glycol based ethers include diethylene glycol diethyl ether, dipropylene glycol dimethyl ether, poly(ethylene glycol) dimethyl ether, etc., including methyl, ethyl, propyl, and butyl mono-and di-ethers of ethylene glycol, and the like.

### Nitriles

In some cases, the organic solvent is a nitrile having a formula R—C□N, where R is aliphatic, haloaliphatic, haloheteroaliphatic, heteroaliphatic, aromatic, aliphatic-aromatic, or heteroaliphatic-aromatic.

In certain embodiments, R can be optionally substituted with a hydroxyl group (e.g., in one example R can be CH₃—CH(OH)—CH₂—, and the organic solvent will be CH₃—CH(OH)—CH₂—CN).

One example nitrile is acetonitrile, mentioned above.

In some embodiments, the organic solvent may include two or more of the organic solvents or types of organic solvents described herein. In some embodiments, water may be provided instead of, or in addition to, the organic solvent.

### Carrier Gas

The carrier gas may be an inert gas. In some cases, the carrier gas is a noble gas. In certain embodiments, the carrier gas may be selected from the group consisting of N2, He, Ne, Ar, Kr, and Xe. In some such embodiments, the carrier gas may be selected from the group consisting of N2, He, and Ar.

### Additive

The additive may be selected from a number of different types of additives. For instance, in some cases, the additive may be a heterocycle compound, a heterocyclic aromatic compound, a halogen-substituted heterocyclic aromatic compound, a heterocyclic aliphatic compound, an amine, a fluoroamine, an amino acid, an organophosphorus compound, an oxidizer, a bifluoride source, ammonia, an aldehyde, a carbene, or an organic acid. In some cases, more than one additive may be used. In some embodiments, the additive may be a boron-containing Lewis acid or Lewis adduct. Boron trifluoride (BF₃) is an example of a Lewis acid that forms the acid-base adduct BF₄⁻. In some cases, the additive may fall into two or more of the categories listed above. In various embodiments, the additive serves the purpose of accelerating the reaction rate and enhancing the reaction selectivity.

### Heterocyclic Aromatic Compounds

In certain embodiments, the additive is a heterocyclic aromatic compound. The term “aromatic” is defined above. A heterocyclic aromatic compound is an aromatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aromatic compounds that may be used include but are not limited to, picoline, pyridine, pyrrole, imidazole, thiophene, N-methylimidazole, N-methylpyrrolidone, benzimidazole, 2,2-bipyridine, dipicolonic acid, 2,6-lutidine, 4-N,N-dimethylaminopyridine, and azulene. In some cases, a heterocyclic aromatic compound may be methylated. In some cases, a heterocyclic aromatic compound may follow the Hückel 4n+2 rule. In some cases, the additive is a halogen-substituted aromatic compound. A halogen-substituted aromatic compound is an aromatic compound that includes at least one halogen bonded to the aromatic ring. As used herein, halogen or halo refers to F, Cl, Br, or I. Example halogen-substituted aromatic compounds include, but are not limited to, 4-bromopyridine, chlorobenzene, 4-chlorotoluene, fluorobenzene, etc.

### Heterocyclic Aliphatic Compounds

In some embodiments, the additive is a heterocyclic aliphatic compound. As used herein, “aliphatic” means a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight-and branched-chain arrangements, and all stereo and position isomers as well. A heterocyclic aliphatic compound is an aliphatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aliphatic compounds include pyrrolidine, piperidine, etc.

### Amines

In some embodiments, the additive is an amine having a formula of NR¹R²R³, where:
each of R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
in which R¹ and R², taken together with the atom to which each is attached, can optionally form a cycloheteroaliphatic; and
in which R¹, R², and R³, taken together with the atom to which each is attached, can optionally form a cycloheteroaliphatic.

In some embodiments, each of R1, R², and R³ is independently selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the amine may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when at least one of R¹, R², and R³ is aliphatic, haloaliphatic, haloheteroaliphatic, or heteroaliphatic, the additive is an alkyl amine. The alkyl amine can include dialkylamines, trialkyl amines, and derivatives thereof. Example alkyl amines include dimethylisopropylamine, N-ethyldiisopropylamine, trimethylamine, dimethylamine, methylamine, triethylamine, t-butyl amine, and the like.

In other embodiments, when at least one of R¹, R², and R³ includes a hydroxyl, the additive is an alcohol amine. In one instance, at least one of R¹, R², and R³ is an aliphatic group substituted with one or more hydroxyls. Example alcohol amines include 2-(dimethylamino)ethanol, 2-(diethylamino)ethanol, 2-(dipropylamino)ethanol, 2-(dibutylamino)ethanol, N-ethyldiethanolamine, N-tertbutyldiethanolamine, and the like.

In some embodiments, when R¹ and R², taken together with the atom to which each is attached, form a cycloheteroaliphatic, the additive can be a cyclic amine. Example cyclic amines include piperidine, N-alkyl piperidine (e.g., N-methyl piperidine, N-propyl piperidine, etc.), pyrrolidine, N-alkyl pyrrolidine (e.g., N-methyl pyrrolidine, N-propyl pyrrolidine, etc.), morpholine, N-alkyl morpholine (e.g., N-methyl morpholine, N-propyl morpholine, etc.), piperazine, N-alkyl piperazine, N, N-dialkyl piperazine (e.g., 1,4-dimethylpiperazine), and the like.

In other embodiments, when at least one of R¹, R², and R³ includes an aromatic, the additive is an aromatic amine. In some embodiments, at least one of R¹, R², and R³ is aromatic, aliphatic-aromatic, or heteroaliphatic-aromatic. In other embodiments, both R¹ and R² include an aromatic. In yet other embodiments, R¹, R², and R³, taken together with the atom to which each is attached, from a cycloheteroaliphatic that is an aromatic. Example aromatic amines include aniline, histamine, pyrrole, pyridine, imidazole, pyrimidine, and the derivatives thereof.

In some embodiments, the additive may include an amine selected from the group consisting of methylamine, dimethylamine, trimethylamine, ethylamine, diethylamine, triethylamine, isopropylamine, 1,2-ethylenediamine, aniline (and aniline derivatives such as N, Ndimethylaniline), N-ethyldiisopropylamine, tert-butylamine, and combinations thereof.

In some embodiments, the additive may include a fluoramine. A fluoramine is an amine having one or more fluorinated substituents. Example fluoroamines that may be used include, but are not limited to, 4-trifluoromethylaniline.

In some embodiments, the additive can be a nitrogenous analog of a carbonic acid, having a formula R¹N—C(NR²)—NR³. Example additives can include, but are not limited to, guanidine or derivatives thereof.

In some embodiments, the additive may be a relatively low molecular weight amine, e.g., having a molecular weight of less than 200 g/mol or 100 g/mol in certain embodiments.

Higher molecular weight amines, including those having long chains and/or heterocyclic compounds with aromatic rings, may be used in some embodiments.

### Amino Acids

In some embodiments, the additive may include an amino acid. The amino acid may have a formula of R—CH(NR′₂)—COOH, where:
each R and R′ independently are hydroxyl, aliphatic, haloaliphatic, haloheteroaliphatic, heteroaliphatic, aromatic, aliphatic-aromatic, heteroaliphatic-aromatic, or any combination thereof.

Example amino acids that may be used include, but are not limited to, histidine, alanine, and derivatives thereof.

### Organophosphorus Compounds

In some embodiments, the additive may include an organophosphorus compound. The organophosphorus compound may be a phosphate ester, a phosphate amide, a phosphonic acid, a phosphinic acid, a phosphonate, a phosphinate, a phosphine oxide, a phosphine imide, or a phosphonium salt. Example organophosphorus compounds include phosphoric acid and trialkylphosphate. In some cases, the organophosphorus compound is a phosphazene. A phosphazene is an organophosphorus compound that includes phosphorus (V) with a double bond between P and N. The phosphazene may have a formula of RN═P(NR₂)₃ (where each of R and R₂ is independently selected from hydroxyl, aliphatic, haloaliphatic, haloheteroaliphatic, heteroaliphatic, aromatic, aliphatic-aromatic, heteroaliphatic-aromatic, or any combination thereof). In some cases, the phosphazene may have a formula of [X₂PN]ₙ (where X is a halide, alkoxide, or amide). Other types of phosphazenes may be used as desired.

### Oxidizers

In some embodiments, the additive includes an oxidizer. As used herein, an oxidizer is a material that has the ability to oxidize (e.g., accept electrons from) another substance.

Example oxidizers that may be used include, but are not limited to, hydrogen peroxide, sodium hypochlorate, and tetramethyl ammonium hydroxide.

### Bifluoride Sources

In some embodiments, the additive includes a bifluoride source. A bifluoride source is a material that includes or produces bifluoride (HF₂⁻). Example bifluoride sources that may be used include, but are not limited to, ammonium fluoride, aqueous hydrogen fluoride, gaseous hydrogen fluoride, buffered oxide etch mixture (e.g., a mixture of hydrogen fluoride and a buffering agent such as ammonium fluoride), and hydrogen fluoride pyridine. In some embodiments, the bifluoride source (and/or one or more of the other additives listed herein) may react to form HF₂⁻ before or after delivery to the reaction chamber.

### Aldehydes

In some embodiments, the additive includes an aldehyde having a formula of X—[C(O)]—H, where:
X can be selected from hydrogen, —R¹, —C(R²)₃ or —[C(R³)₂]ₘ—C(O)H, wherein each R1, R², and R³ independently are selected from hydrogen, aliphatic, haloaliphatic, haloheteroaliphatic, heteroaliphatic, aromatic, aliphatic-aromatic, heteroaliphatic-aromatic, or any combinations thereof, and m is an integer from 0 to 10.

In some embodiments, each of R¹, R², and R³ is, independently, alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the aldehyde or ketone may further be substituted with one or more substituents, such as aldehyde (—C(O)H), oxo (═O), alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X=aromatic, the additive can be an aromatic aldehyde. Example aromatic aldehydes include benzaldehyde, 1-naphthaldehyde, phthalaldehyde, and the like.

In other embodiments, when X=aliphatic, the additive can be an aliphatic aldehyde. Example aliphatic aldehydes include acetaldehyde, propionaldehyde, butyraldehyde, isovalerylaldehyde, and the like.

In yet other embodiments, when X═—[C(R³)₂]ₘ—C(O)H and m is 0 to 10 or when X=aliphatic or heteroaliphatic substituted with —C(O)H, the additive can be a dialdehyde. Example dialdehydes include glyoxal, phthalaldehyde, glutaraldehyde, malondialdehyde, succinaldehyde, and the like.

In some examples, an aldehyde used as an additive may be selected from the group consisting of acrolein, acetaldehyde, formaldehyde, benzaldehyde, propionaldehyde, butyraldehyde, cinnamaldehyde, vanillin, and tolualdehyde. In these or other cases, an aldehyde used as an additive may be selected from the aldehydes discussed in this section and the aldehydes discussed in the organic solvent section.

### Carbenes

In some embodiments, the additive includes a carbene. The carbene may have a formula of X—(C:)—Y, where:
each of X and Y can be independently selected from H, halo, —[C(R¹)₂]ₘ—C(R²)₃, —C(O)—R¹, or —C(═NR¹)—R², —NR¹R², —OR², —SR², or —C(R²)₃, wherein each of R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10;
in which R¹ and R², taken together with the atom to which each is attached, can optionally form a cycloheteroaliphatic group; and
in which X and Y, taken together with the atom to which each is attached, can optionally form a cycloaliphatic or cycloheteroaliphatic group.

Furthermore, the additive can be a carbenium cation having a formula R¹—C⁺(R)—R², wherein each of R, R¹, and R² is independently selected from hydrogen, aliphatic, haloaliphatic, haloheteroaliphatic, heteroaliphatic, aromatic, aliphatic-aromatic, heteroaliphatic-aromatic, or any combinations thereof.

In some embodiments, each R, R¹, and R² independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the carbene may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof. In any embodiment of a carbene, each of R¹ and R² can be independently selected.

In some embodiments, when at least one of X or Y is halo, the additive can be a halocarbene. Examples of non-limiting halocarbenes include dihalocarbene, such as dichlorocarbene, difluorocarbene, and the like.

In some embodiments, when both X═Y═—NR¹R², the additive can be a diaminocarbene. In one instance, each of R¹ and R² is independently aliphatic. Examples of diaminocarbenes include bis(diisopropylamino) carbene, and the like.

In other embodiments, when both at least one of X or Y═—NR¹R² and both R¹ and R² within X or within Y are taken together, with the nitrogen atom to which each is attached, to form a cycloheteroaliphatic group, the additive can be a cyclic diaminocarbene. Example cyclic diamino carbenes include bis(N-piperidyl) carbene, bis(N-pyrrolidinyl) carbene, and the like.

In one instance, when both X═Y═—NR¹R² and an R¹ group from X and an R² group from Y are taken together, with the nitrogen atom to which each is attached, to form a cycloheteroaliphatic group, the additive is an N-heterocyclic carbene. Example N-heterocyclic carbenes include imidazol-2-ylidenes (e.g., 1,3-dimesitylimidazol-2-ylidene, 1,3-dimesityl-4,5-dichloroimidazol-2-ylidene, 1,3-bis(2,6-diisopropylphenyl)imidazol-2-ylidene, 1,3-di-tert-butylimidazol-2-ylidene, etc.), imidazolidin-2-ylidenes (e.g., 1,3-bis(2,6-diisopropylphenyl)imidazolidin-2-ylidene), triazol-5-ylidenes (e.g., 1,3,4-triphenyl-4,5-dihydro-1H-1,2,4-triazol-5-ylidene), and the like.

In some embodiments, when X═—NR¹R² and Y═—SR² and an R¹ group from X and an R² group from Y are taken together, with the nitrogen atom to which each is attached, to form a cycloheteroaliphatic group, the additive is acyclic thioalkyl amino carbene. Example cyclic thioalkyl amino carbenes include thiazol-2-ylidenes (e.g., 3-(2,6-diisopropylphenyl)thiazol-2-ylidene, and the like).

In some embodiments, when X═—NR¹R² and Y═—C(R²)₃ and an R¹ group from X and an R² group from Y are taken together, with the atom to which each is attached, to form a cycloheteroaliphatic group, the additive is a cyclic alkyl amino carbene. Example cyclic alkyl amino carbenes include pyrrolidine-2-ylidenes (e.g., 1,3,3,5,5-pentamethyl-pyrrolidin-2-ylidene and the like) and piperidin-2-ylidenes (e.g., 1,3,3,6,6-pentamethyl-piperidin-2-ylidene and the like).

Further example carbenes and derivatives thereof include compounds having a thiazol-2-ylidene moiety, a dihydroimidazol-2-ylidene moiety, an imidazol-2-ylidene moiety, a triazol-5-ylidene moiety, or a cyclopropenylidene moiety. Yet other carbenes and carbene analogs include an aminothiocarbene compound, an aminooxycarbene compound, a diaminocarbene compound, a heteroamino carbene compound, a 1,3-dithiolium carbene compound, a mesoionic carbene compound (e.g., an imidazolin-4-ylidene compound, a 1,2,3-triazolylidene compound, a pyrazolinylidene compound, a tetrazol-5-ylidene compound, an isoxazol-4-ylidene compound, a thiazol-5-ylidene compound, etc.), a cyclic alkyl amino carbene compound, a boranylidene compound, a silylene compound, a stannylene compound, a nitrene compound, a phosphinidene compound, a foiled carbene compound, etc. Further example carbenes include dimethyl imidazol-2-ylidene, 1,3-bis(2,4,6-trimethylpheny1)-4,5-dihydroimidazol-2-ylidene, (phosphanyl)(trifluoromethyl)carbene, bis(diisopropylamino) carbene, bis(diisopropylamino) cyclopropenylidene, 1,3-dimesityl-4,5-dichloroimidazol-2-ylidene, 1,3-diadamantylimidazol-2-ylidene, 1,3,4,5-tetramethylimidazol-2-ylidene, 1,3-dimesitylimidazol-2-ylidene, 1,3-dimesitylimidazol-2-ylidene, 1,3,5-triphenyltriazol-5-ylidene, bis(diisopropylamino) cyclopropenylidene, bis(9-anthryl)carbene, norbornen-7-ylidene, dihydroimidazol-2-ylidene, methylidenecarbene, etc.

Organic Acids:

In some embodiments, the additive includes an organic acid. The organic acid may have a formula of R-CO2H, wherein R is selected from hydrogen, aliphatic, haloaliphatic, haloheteroaliphatic, heteroaliphatic, aromatic, aliphatic-aromatic, heteroaliphatic-aromatic or any combinations thereof. In certain embodiments, R is alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heteroaryl, alkyl-aryl, alkenyl-aryl, alkynyl-aryl, alkyl-heteroaryl, alkenyl-heteroaryl, alkynyl-heteroaryl, heteroalkyl-aryl, heteroalkenyl-aryl, heteroalkynyl-aryl, heteroalkyl-heteroaryl, heteroalkenyl-heteroaryl, heteroalkynyl-heteroaryl or any combinations thereof. In particular disclosed embodiments, R may further be substituted with one or more substituents such as alkoxy, amide, amine, thioether, hydroxyl, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide or any combinations thereof. In certain implementations, the organic acid may be selected from formic acid and acetic acid.

### Substitutions

Any of the example materials described herein include unsubstituted and/or substituted forms of the compound. Non-limiting example substituents include, e.g., one, two, three, four, or more substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each is attached, form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkoxy (e.g., —S—R, in which R is C₁₋₆ alkyl); (21) thiol (e.g., —SH); (22) CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (24) SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C¹⁻⁶ alkyl and R is C⁴⁻¹⁸ aryl); (25) SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); and (26) NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group.

In certain embodiments, the additive may act as a proton acceptor and promote the formation of HF₂⁻. In some such cases, the HF₂⁻ may actively etch one or more materials on the substrate such as an oxide material or another material.

Thermal energy is provided. In some embodiments, the thermal energy provides heat that drives a chemical reaction. In some embodiments, the thermal energy is plasma free. In some embodiments, the thermal energy is internal or kinetic energy. In some embodiments, the thermal energy is applied as at least at least one of heat or chemical energy. In some embodiments, light sources emitting optical or infrared light may be used to provide thermal energy to a surface of the stack 200. In some embodiments, radiant heat may be used to provide thermal energy to the surface of the stack 200. In some embodiments, an object, such as a substrate support, is in physical contact with the stack 200 through a substrate and provides thermal energy through the physical contact.

FIG. 2B is a schematic cross-sectional view of the stack 204 after features 224 have been partially etched into the layer of silicon oxide.

### Passivation Step

After the thermal etch step (step 112) of part of the stack 204, the next phase of the cyclical process (step 108) is a passivation step (step 116). In some embodiments, the passivation provides a deposition that is at least one of carbon-based, tungsten-based, molybdenum-based, and sulfur-based on the sidewalls of the features. In some embodiments, the passivation is provided by a plasma based deposition. In some embodiments, the passivation is provided by a thermal deposition. In some embodiments, the thermal deposition is plasma free. In some embodiments, the passivation is provided by at least one of atomic layer deposition (ALD), chemical vapor deposition (CVD), and by a self-assembled monolayer (SAM). In some embodiments, the passivation provides a carbon-based deposition on the sidewalls of the features. In some embodiments, a carbon-based deposition is deposited on sidewalls using CVD.

FIG. 2C is a schematic cross-sectional view of the stack 204 after a passivation layer 228 has been deposited on sidewalls of the features 224. The passivation layer 228 is not drawn to scale in order to better illustrate the passivation layer 228.

### Breakthrough Step

A breakthrough step (step 120) is provided in some embodiments. In some embodiments, the breakthrough step (step 120) may be at least one of a plasma etch and chemical etch. In some embodiments, the breakthrough step uses a plasma etch. In some embodiments, a breakthrough step (step 120) is not needed when no or little passivation is deposited on the etch front or when the subsequent etch step is able to etch through the passivation layer deposited on the etch front.

FIG. 2D is a schematic cross-sectional view of the stack 204 after a breakthrough step (step 120) has been provided. The passivation layer 228 at the etch front has been removed while leaving the passivation layer 228 that has been deposited on the sidewalls of the features 224.

The cyclical process step 108 is repeated a plurality of times until the etch is completed. FIG. 2E is a schematic cross-sectional view of the stack 204 after the etching of the features 224 is completed. Additional processes may be performed on the stack 204 in the chamber (step 124). The stack 204 is removed from the chamber (step 128). In the embodiments shown in the flow chart of FIG. 1, all of the process steps are performed in-situ in the same chamber.

An advantage of the disclosed techniques is that they achieve a high degree of selectivity during etching. Another advantage of the disclosed techniques is that they provide extremely precise control of the etching rate and etch removal amount, especially compared to other thermally-driven etch processes. By providing a cyclical passivation process sidewall etching that might be caused by the thermal etch process is reduced or eliminated, thus providing more uniform feature widths. In addition, some embodiments reduce SiN mask recess to be less than 1.0 nanometers (nm).

The advantages of some embodiments are the ability of a device manufacturer to be able to have more precise control of the profile of a high aspect feature. Thermal etches are inherently isotropic processes. By providing sidewall protection, the resulting cyclical process is more anisotropic. Various embodiments enable increasing the bottom CD for very high aspect ratio features. Various embodiments enable next generations of devices that rely on deeper structures with higher aspect ratios. Various embodiments reduce the cost of device manufacturing by reducing the number of steps for the development of high aspect ratio contacts. Various embodiments reduce the variation of the width of the features along the depth of the features so that the difference between widths at any two points along the depth of the features 240 is less than 5 %. The thermal etch allows for selective etching of silicon oxide with respect to silicon nitride, silicon, silicon carbide, silicon germanium, and metal containing layers.

### CYCLE OF THERMAL ETCHING WITH PLASMA ETCHING

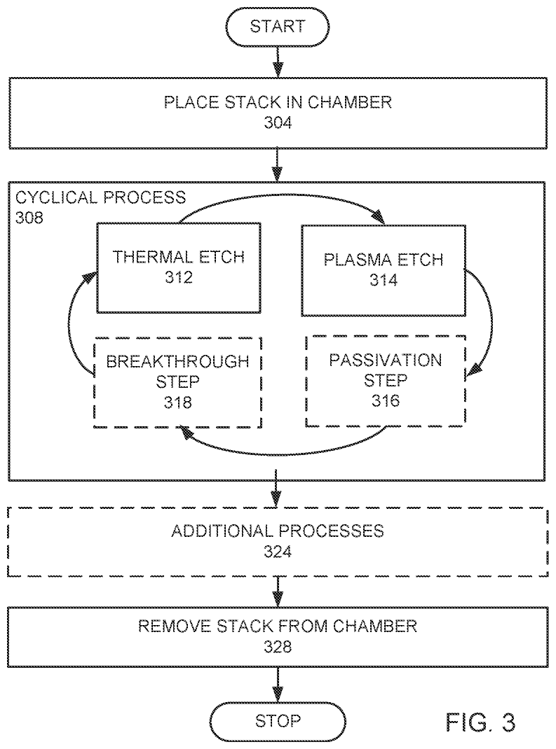

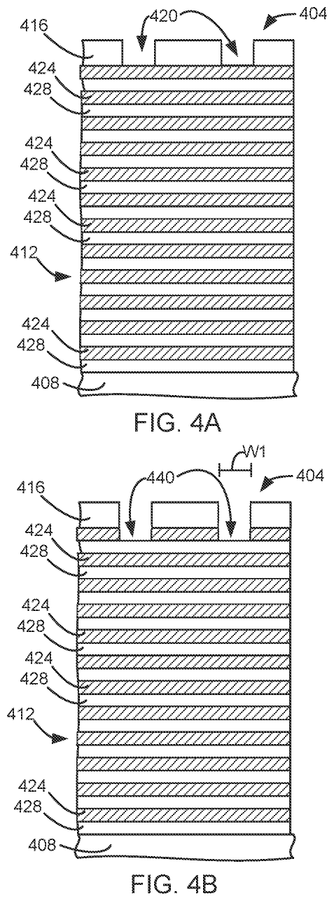

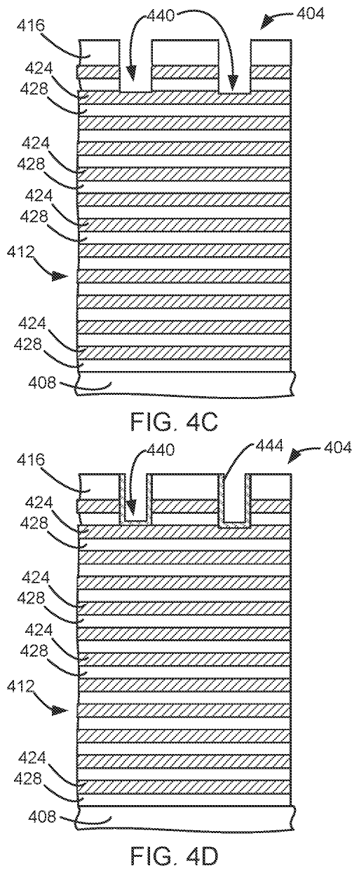

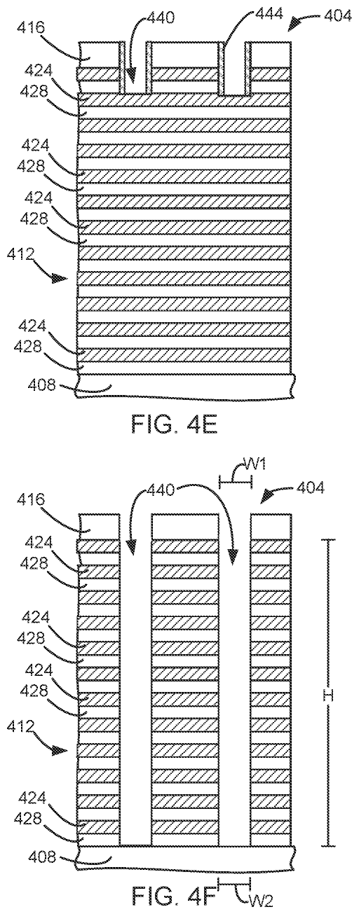

In some embodiments, a cyclical process of thermal etching and plasma etching is provided. FIG. 3 is a high level flow chart that may be used in some embodiments. In some embodiments, a stack is placed in an etch chamber (step 304). FIG. 4A is a schematic cross-sectional view of a stack 404. In some embodiments, the stack 404 comprises a substrate 408 under a plurality of bilayers 412 disposed below a patterned mask 416. In some embodiments, one or more layers may be disposed between the substrate 408 and the plurality of bilayers 412 and/or the plurality of bilayers 412 and the patterned mask 416. In some embodiments, the patterned mask 416 is a carbon containing patterned mask, such as amorphous carbon. Some embodiments do not have a silicon containing mask above the plurality of bilayers 412 or above the patterned mask 416. In this example, the patterned mask pattern provides mask features 420 for high aspect ratio contacts. In some embodiments, the mask features 420 are formed before the stack 404 is placed in the etch chamber. In other embodiments, the mask features 420 are formed while the stack 404 is in the etch chamber. In some embodiments, each bilayer 412 includes a layer of silicon oxide 424 and a layer of silicon nitride 428.

A cyclical process (step 308) is provided to etch the stack. In some embodiments, the cyclical process (step 308) comprises one or more cycles of a thermal etch step (step 312), a plasma etch (step 314), a passivation step (step 316), and a breakthrough step (step 318). In some embodiments, the processes are performed in-situ in the same processing chamber. In some embodiments, the cyclical process (step 308) does not have a passivation step (step 316) and/or a breakthrough step (step 318).

The thermal etch step (step 312) may be like the thermal etch step (step 112) described above to selectively etch a layer of silicon oxide 424 with respect to one or more layers of silicon nitride 428. FIG. 4B is a schematic cross-sectional view of a stack 404 after a thermal etch step (step 312), where the thermal etch step (step 312) etches etch features 440 in an exposed layer of silicon oxide 424 exposing a layer of silicon nitride 428.

After the thermal etch step (step 312) a plasma etch is provided (step 314). The plasma etch provides an etch gas and forms the etch gas into a plasma. In some embodiments, RF energy is used to transform the etch gas into a plasma. The plasma is used to provide a plasma etch. The plasma etch etches a layer of silicon nitride 428. FIG. 4C is a schematic cross-sectional view of a stack 404 after a plasma etch (step 314), where the plasma etch step (314) further etches etch features 440 in an exposed layer of silicon nitride 428 exposing a layer of silicon oxide 424. In some embodiments, the plasma etch (step 314) partially etches the exposed layer of silicon oxide.

After the plasma etch (step 314) a passivation step may be provided (step 316). In some embodiments, the passivation provides a deposition that is at least one of carbon-based, tungsten-based, molybdenum-based, and sulfur-based on the sidewalls of the features. In some embodiments, the passivation is provided by a plasma based deposition. In some embodiments, the passivation is provided by a thermal deposition. In some embodiments, the thermal deposition is plasma free. In some embodiments, the passivation is provided by at least one of atomic layer deposition (ALD), chemical vapor deposition (CVD), and by a self-assembled monolayer (SAM). In some embodiments, the passivation provides a carbon-based deposition on the sidewalls of the features. FIG. 4D is a schematic cross-sectional view of a stack 404 after the passivation step (step 316) has been provided forming a passivation layer 444.

After the passivation step (step 316) a breakthrough step may be provided (step 318). In some embodiments, the breakthrough step (step 318) may be at least one of a plasma etch and chemical etch. In some embodiments, the breakthrough step (step 318) is a plasma etch using bombardment ions. In some embodiments, a breakthrough step (step 318) is not needed when no or little passivation is deposited on the etch front or when the subsequent etch step is able to etch through the passivation layer deposited on the etch front. FIG. 4E is a schematic cross-sectional view of a stack 404 after the breakthrough step (step 318) has been provided. The passivation layer 444 at the etch front has been removed while leaving the passivation layer 444 that has been deposited on the sidewalls of the etch features 440.

The cyclical process is repeated a plurality of times until the etch features 440 are completed. FIG. 4F is a schematic cross-sectional view of a stack 404 after the etch features 440 are completed. Additional processes may be performed on the stack 404 in the chamber (step 324). The stack 404 is removed from the chamber (step 328). In the embodiments shown in the flow chart of FIG. 3, all of the process steps are performed in-situ in the same chamber.

The cyclical process (step 308) of performing a thermal etch step (step 312) and a plasma etch (step 314) allows for more control parameters for etching bilayers of silicon oxide and another material. The thermal etch step (step 312) provides a selective etch of silicon oxide, and the plasma etch (step 314) provides an etch of another material. The thermal etch is able to etch silicon oxide faster than the plasma etch. The addition of a passivation step (step 316) allows for the etching of deeper layers of silicon oxide 424 without lateral etching of the sidewalls of the silicon oxide layer 424 that were previously etched. The thermal etch allows the etching of silicon oxide at high aspect ratios with reduced twisting and non-circularity. Some embodiments provide a high ratio of depth H to width W1, shown in FIG. 4E. In addition, the variation of W1 along the depth is reduced. In addition, the feature width at the top of the feature W1 is close to the feature width at the bottom of the feature W2. In some embodiments, the depth H to width W1 aspect ratio is in the range of 4:1 to 20:1. In some embodiments, the width W1 has a CD in the range of 10 nm to 50 nm.

In some embodiments, bilayers of silicon oxide and other materials in a stack may be etched. In some embodiments, trilayers with a layer of silicon oxide and two layers of two other materials may be etched. In some embodiments, in order to etch the trilayers a cyclical process comprising a thermal etch and a single plasma etch may be used. In some embodiments, in order to etch the trilayers a cyclical process comprising a thermal etch followed by two separate etch processes may be used. In the specification and claims, at least bilayers include bilayers, trilayers, and higher multiple layers placed together. The trilayers and higher multiple layers may be layers of different materials or may have some layers of the same material, where not all layers are of the same material. In some embodiments, the thermal etch is a plasma free etch. In some embodiments, a plasma may be provided during thermal etching to avoid plasma restrike and/or avoid etch stop due to sputtering of sidewall material to the etch front.

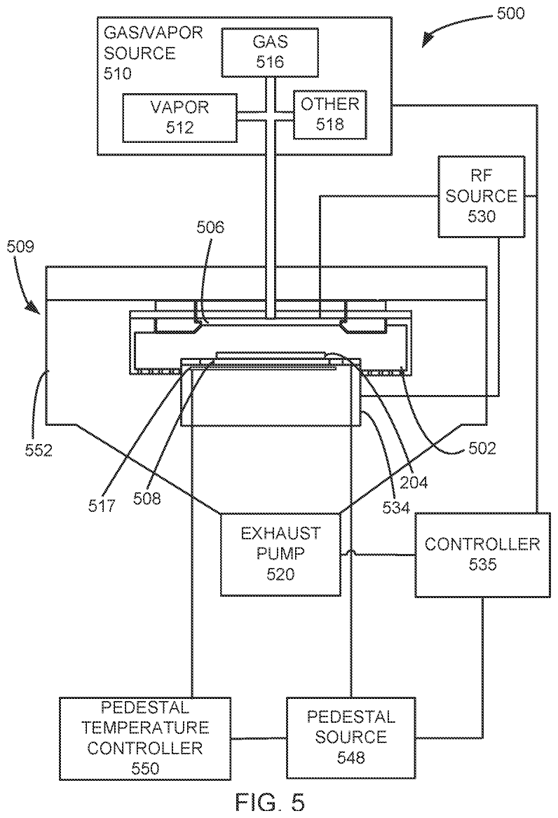

FIG. 5 is a schematic view of an etch reactor system 500 that may be used in some embodiments. In some embodiments, an etch reactor system 500 comprises a gas/vapor distribution plate 506 providing a gas and vapor inlet and a pedestal 508, within an etch chamber 509, enclosed by a chamber wall 552. Within the etch chamber 509, a stack 204 is positioned over the pedestal 508, where the pedestal 508 acts as a wafer support. The pedestal 508 may provide a bias from the pedestal source 548. A gas/vapor source 510 is connected to the etch chamber 509 through the gas/vapor distribution plate 506. In some embodiments, the gas/vapor source 510 comprises a vapor source 512, a gas source 516, and may further comprise other sources 518. The vapor source 512 comprises a halogen vapor source and a vapor catalyst source. The gas source 516 comprises at least one of a passivation gas source and an etch plasma gas source. A pedestal temperature controller 550 is connected to the pedestal 508. The pedestal temperature controller 550 may be used to heat the pedestal through a pedestal heater 517 in order to provide thermal energy. In other embodiments, the thermal energy may be provided through other heater configurations. A plasma power source, such as a radio frequency (RF) source 530, provides power to a lower electrode and/or an upper electrode, which in some embodiments are the pedestal 508 and the gas/vapor distribution plate 506, respectively. In some embodiments, 400 kilohertz (kHz), 60 megahertz (MHz), and optionally, 2 MHz and 27 MHz power sources make up the RF source 530 and the pedestal source 548. In some embodiments, the upper electrode is grounded. In some embodiments, one generator is provided for each frequency. In other embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. An exhaust pump 520 provides an outlet for exhausting gases from the etch chamber 509. A controller 535 is controllably connected to the RF source 530, the pedestal source 548, the exhaust pump 520, and the gas/vapor source 510. An example of such an etch chamber is the Flex™M etch system manufactured by Lam Research Corporation of Fremont, CA. The process chamber can be a CCP (capacitively coupled plasma) reactor or an ICP (inductively coupled plasma) reactor. In some embodiments, the cyclical process is performed in-situ in the etch chamber 509 while the stack 204 is supported on the pedestal 508.

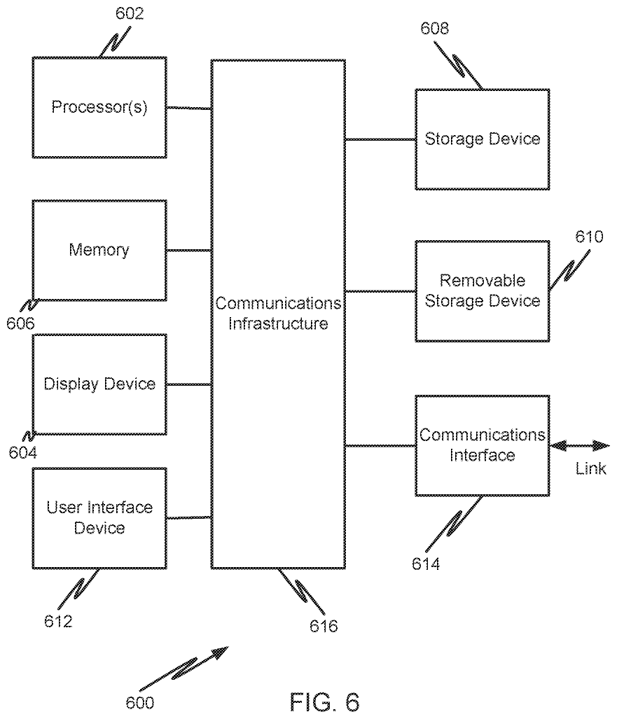

FIG. 6 is a high level block diagram showing a computer system 600, which is suitable for implementing the controller 535 used in embodiments. The computer system 600 may have many physical forms ranging from an integrated circuit, a printed circuit board, and a small handheld device up to a huge supercomputer. The computer system 600 includes one or more processors 602 and further can include an electronic display device 604 (for displaying graphics, text, and other data), a main memory 606 (e.g., random access memory (RAM)), storage device 608 (e.g., hard disk drive), removable storage device 610 (e.g., optical disk drive), user interface devices 612 (e.g., keyboards, touch screens, keypads, mice or other pointing devices, etc.), and a communications interface 614 (e.g., wireless network interface).

The communications interface 614 allows software and data to be transferred between the computer system 600 and external devices via a link. The system may also include a communications infrastructure 616 (e.g., a communications bus, cross-over bar, or network) to which the aforementioned devices/modules are connected.

Information transferred via communications interface 614 may be in the form of signals such as electronic, electromagnetic, optical, or other signals capable of being received by communications interface 614, via a communications link that carries signals and may be implemented using wire or cable, fiber optics, a phone line, a cellular phone link, a radio frequency link, and/or other communications channels. With such a communications interface 614, it is contemplated that the one or more processors 602 might receive information from a network or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that is executed by a computer using an interpreter. Computer readable media may also be computer code transmitted by a computer data signal embodied in a carrier wave and representing a sequence of instructions that are executable by a processor.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for etching features in a stack, comprising providing a plurality of cycles, wherein each cycle comprises:
a) providing a thermal etch step for etching the features in the stack, wherein the stack comprises at least one silicon oxide layer, the thermal etch step comprising:
providing a thermal etch gas in vapor phase, comprising:
a halogen containing vapor or gas; and
a vapor catalyst; and
providing thermal energy to drive a reaction that etches the features in the stack; and
b) providing a passivation step for depositing a passivation layer on sidewalls of the features.

2. The method, as recited in claim 1, wherein, the providing the passivation provides a deposition that is at least one of carbon-based, tungsten-based, molybdenum-based, and sulfur-based.

3. The method, as recited in claim 1, wherein the providing the passivation is provided by at least one of chemical vapor deposition, chemical vapor deposition, self-assembled monolayer, and atomic layer deposition.

4. The method, as recited in claim 1, wherein each cycle further comprises c) providing a breakthrough of the passivation.

5. The method, as recited in claim 4, wherein the providing the thermal etch, the providing the passivation, and the providing the breakthrough are performed in-situ in a chamber.

6. The method of claim 1, wherein the providing the thermal etch and the providing the passivation are performed in-situ in a chamber.

7. The method of claim 1, wherein the providing the thermal etch further comprises providing a pressure between about 0.2-10 Torr.

8. The method of claim 1, wherein the halogen containing vapor or gas is a hydrogen fluoride containing vapor or gas.

9. The method of claim 1, wherein the providing the passivation provides a carbon-based deposition.

10. The method of claim 1, wherein the vapor catalyst, comprises:
an organic solvent and/or water;
an additive; and
a carrier gas.

11. The method, as recited in claim 10, wherein the additive comprises a heterocycle.

12. The method of claim 10, wherein the additive comprises an amine.

13. A method for etching features in a stack, comprising providing a plurality of cycles, wherein each cycle comprises:
a) providing a plasma etch; and
b) providing a thermal etch for etching features in the stack, wherein the stack comprises at least bilayers, wherein at least one layer of the at least bilayers is a silicon oxide layer, comprising:
providing a thermal etch gas in vapor phase, comprising:
a halogen containing vapor or gas; and
a vapor catalyst; and
providing thermal energy to drive a reaction that etches features in the stack.

14. The method of claim 13, wherein the providing the thermal etch further comprises providing a pressure between about 0.2-10 Torr.

15. The method of claim 13, wherein each cycle further comprises c) providing a passivation for depositing a passivation layer on sidewalls of the features.

16. The method of claim 15, wherein each cycle further comprises d) providing a breakthrough of the passivation.

17. The method, as recited in claim 16, wherein providing the plasma etch, the providing the thermal etch, the providing the passivation, and the providing the breakthrough are performed in-situ in a chamber.

18. The method, as recited in claim 15, wherein providing the plasma etch, the providing the thermal etch, and the providing the passivation are performed in-situ in a chamber.

19. The method of claim 15, wherein the providing the passivation provides a carbon-based deposition.

20. The method, as recited in claim 13, wherein the halogen containing vapor or gas comprises a hydrogen fluoride vapor or gas.

21. The method of claim 13, wherein the vapor catalyst, comprises:
an organic solvent and/or water;
an additive; and
a carrier gas.

22. An apparatus for etching a substrate, the apparatus comprising:
a. a reaction chamber configured to provide a pressure between about 0.2-10 Torr in the reaction chamber;
b. a substrate support configured to support the substrate in the reaction chamber;
c. at least one inlet for introducing a gas mixture to the reaction chamber;
d. a halogen vapor or gas source for providing a halogen vapor or gas to the at least one inlet;
e. a vapor catalyst source for providing a vapor catalyst to the at least one inlet;
f. at least one of a passivation gas source and an etch plasma gas source connected to the at least one inlet;
g. a heater for providing thermal energy to the substrate;
h. an outlet for removing vapor from the reaction chamber; and
f. a controller configured to provide a cyclical process, wherein the cyclical process, comprising:
a thermal etch step; and
at least one of a passivation step and a plasma etch.

23. The apparatus, as recited in claim 22, further comprising a plasma power source for providing plasma energy to the reaction chamber.
